(19) United States
(12) Patent Application Publication
(10) Pub. No.: US 2024/0136234 A1
(43) Pub. Date: Apr. 25, 2024

(54) METHOD OF MEASURING OVERLAY OFFSET AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Mingyoo CHOI, Suwon-si (KR); Jinsun Kim, Suwon-si (KR); Seunghak Park, Suwon-si (KR); Jongsu Park, Suwon-si (KR); Sunkak Jo, Suwon-si (KR)

(21) Appl. No.: 18/380,691

(22) Filed: Oct. 17, 2023

(30) Foreign Application Priority Data
Oct. 17, 2022 (KR) 10-2022-0133609

(51) Int. Cl. H01L 21/66; H01L 21/311

(52) U.S. Cl. CPC H01L 22/12; H01L 21/31116

(57) ABSTRACT

A method of measuring an overlay offset, the method includes: providing a substrate including a lower pattern and an upper pattern, wherein the lower pattern is disposed in a cell area, and the upper pattern is disposed on the lower pattern; acquiring a first piece of overlay information about a first position of the lower pattern and a second position of the upper pattern by detecting a pupil image of a joint position that is between the upper pattern and the lower pattern; detecting an overlay offset of the second position of the upper pattern relative to the first position of the lower pattern through Zernike polynomial modeling; and acquiring compensation overlay information on the upper pattern from the overlay offset of the second position, wherein the overlay offset includes a radial tilting component.

### CROSS-REFERENCE TO RELATED APPLICATION

This application claims priority under 35 U.S.C. § 119 to Korean Patent Application No. 10-2022-0133609, filed on Oct. 17. 2022, in the Korean Intellectual Property Office, the disclosure of which is incorporated by reference herein in its entirety.

### TECHNICAL FIELD

The present inventive concept relates to an overlay offset measurement method and a semiconductor device manufacturing method using the overlay offset measuring method, and more particularly to, an overlay offset measurement method including in-cell overlay offset measurement and correction, and a semiconductor device manufacturing method using the overlay offset measurement method.

### DISCUSSION OF THE RELATED ART

Semiconductor design rules try to achieve size reduction, and thus, the desire for techniques for measuring the overlay between an upper pattern and a lower pattern has increased. In addition, measurement methods of the related art that use dedicated overlay keys provided in scribe lanes have limitations in representing overlay offsets of patterns in an actual cell according to the physical distance between the overlay keys and the patterns in the actual cell. To address this situation, techniques for measuring overlay offsets between actual patterns in a cell have been under development.

### SUMMARY

According to an embodiment of the present inventive concept, a method of measuring an overlay offset, the method includes: providing a substrate including a lower pattern and an upper pattern, wherein the lower pattern is disposed in a cell area, and the upper pattern is disposed on the lower pattern; acquiring a first piece of overlay information about a first position of the lower pattern and a second position of the upper pattern by detecting a pupil image of a joint position that is between the upper pattern and the lower pattern; detecting an overlay offset of the second position of the upper pattern relative to the first position of the lower pattern through Zernike polynomial modeling; and acquiring compensation overlay information on the upper pattern from the overlay offset of the second position, wherein the overlay offset includes a radial tilting component.

According to an embodiment of the present inventive concept, a method of measuring an overlay offset, the method includes: providing a substrate including a lower channel hole and an upper channel hole, wherein the lower channel hole is disposed in a cell area, and the upper channel hole is disposed on the lower channel hole; acquiring a first piece of overlay information about a first position of the lower channel hole and a second position of the upper channel hole by detecting a pupil image of a joint position that is between the lower channel hole and the upper channel hole; detecting an overlay offset of the second position of the upper channel hole relative to the first position of the lower channel hole through Zernike polynomial modeling; and acquiring compensation overlay information on the upper channel hole from the overlay offset of the second position, wherein the overlay offset is caused by a radial tilting error of the upper channel hole.

According to an embodiment of the present inventive concept, a method of manufacturing a semiconductor device, the method includes: forming a lower stack in a cell area of a substrate, wherein the lower stack includes a lower channel hole; forming an upper stack on the lower stack, wherein the upper stack includes an upper channel hole; acquiring a first piece of overlay information about a first position of the lower channel hole and a second position of the upper channel hole by detecting a pupil image of a joint position that is between the upper channel hole and the lower channel hole; detecting an overlay offset of the second position of the upper channel hole relative to the first position of the lower channel hole through Zernike polynomial modeling; and acquiring compensation overlay information on the upper channel hole from the overlay offset of the second position, wherein the overlay offset includes a radial tilting component.

### BRIEF DESCRIPTION OF THE DRAWINGS

The above and other aspects of the present inventive concept will become more apparent by describing in detail embodiments thereof, with reference to the accompanying drawings, in which:

FIG. 1 is a schematic structural diagram illustrating an overlay measurement system according to an embodiment of the present inventive concept;

FIG. 2 is a flowchart illustrating an overlay measurement method according to an embodiment of the present inventive concept;

FIG. 3 is a schematic diagram illustrating a substrate used in an overlay offset measurement method according to an embodiment of the present inventive concept;

FIG. 4 is an enlarged view illustrating a portion A of FIG. 3;

FIG. 5 is a diagram schematically illustrating a plurality of segments defined in a shot area;

FIG. 6 is a diagram illustrating Zernike polynomials having a radial order within the range of 0 to 5;

FIGS. 7A and 7B are schematic diagram illustrating overlay offset mapping values as examples;

FIG. 8 is an overlay vector diagram obtained by an overlay measurement method using a Cartesian coordinate system according to a comparative example;

FIG. 9 is an overlay vector diagram obtained by an overlay measurement method according to an embodiment of the present inventive concept;

FIG. 10 is a graph illustrating overlay offsets of measurement samples according to a comparative example, and overlay offsets of measurement samples according to an embodiment of the present inventive concept;

FIG. 11 is a graph illustrating a correlation between overlay offset values measured by a non-destructive overlay measurement method according to an embodiment of the present inventive concept and overlay offset values measured by a destructive measurement method; and

FIGS. 12A, 12B, 13A, 13B, 14A, 14B, 15A, 15B, 16A, and 16B are schematic diagrams illustrating a method of manufacturing a semiconductor device according to an embodiment of the present inventive concept.

### DETAILED DESCRIPTION OF THE EMBODIMENTS

Hereinafter, embodiments of the present inventive concept will be described with reference to the accompanying drawings.

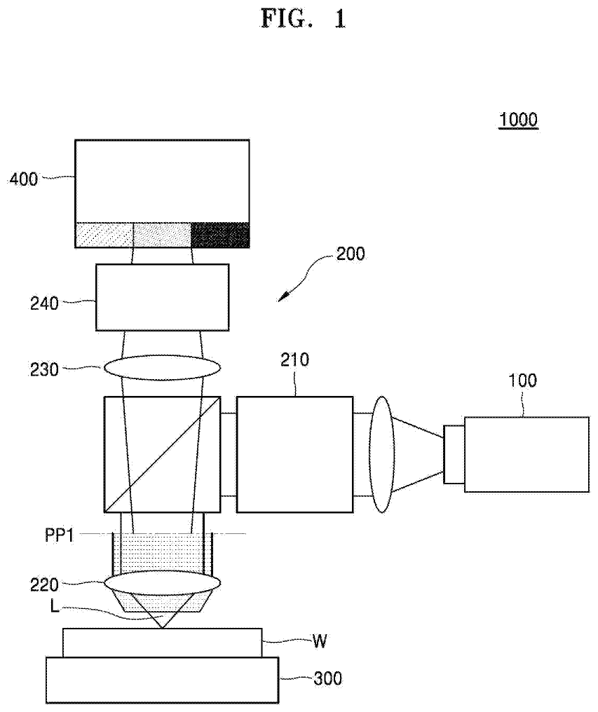

FIG. 1 is a schematic structural diagram illustrating an overlay measurement system 1000 according to an embodiment of the present inventive concept.

Referring to FIG. 1, the overlay measurement system 1000 may include a pupil image-based overlay measurement device. The overlay measurement system 1000 may be used to obtain a pupil image by emitting light to a cell area of a substrate W such as a semiconductor substrate on which a multilayer structure is formed, and measure the overlay between an upper layer and a lower layer of the multilayer structure by analyzing the pupil image. In some embodiments of the present inventive concept, the overlay measurement system 1000 may be used to non-destructively measure the overlay between a previously-patterned first layer and a currently-patterned second layer in a process of manufacturing a semiconductor device such as a dynamic random access memory (DRAM) device or a vertical NAND (VNAND) memory device.

The overlay measurement system 1000 may include a light source 100, an optical system 200, a stage 300, and a detector 400.

The light source 100 may be configured to generate and output light L. Light L output by the light source 100 may be laser light. Laser light output from the light source 100 may be a pulse laser beam, for example, a laser beam having a pulse width of about 500 Hz to about 1 kHz. In some embodiments of the present inventive concept, light L output from the light source 100 may be a continuous wave laser beam. The light source 100 may generate and output light having various wavelengths. For example, the light source 100 may generate and output light having a wavelength of about 200 nm, such as 248 nm (KrF), 193 nm (ArF), or 157 nm (F₂).

The optical system 200 may transmit light L output from the light source 100 to the substrate W. The optical system 200 may include a polarization controller 210, a high numerical aperture (HNA) condenser 220, a relay lens 230, and a polarization state analyzer 240.

The polarization controller 210 may control the polarization state of light L that is emitted from the light source 100 by using a polarizing filter. For example, the polarization controller 210 may polarize light L that is emitted from the light source 100 to obtain linearly polarized light, circularly polarized light, or elliptically polarized light by using the polarization filter. In some embodiments of the present inventive concept, an additional optical system such as a beam splitter may be disposed between the polarization controller 210 and the light source 100.

The HNA condenser 220 may be a certain type of objective lens configured to focus light and may have a large numerical aperture (NA) within the range of about 1 or more. For example, the HNA condenser 220 may focus a first light beam L1 and may irradiate the substrate W with the first light beam L1. In some embodiments of the present inventive concept, a medium NA (MNA) condenser having an NA of less than about 1 may be used. Furthermore, in some embodiments of the present inventive concept, the HNA condenser 220 and the MNA condenser may be used together.

The substrate W may be disposed on the stage 300. The stage 300 may support and fix the substrate W. The stage 300 may support and fix a bottom surface or a side surface of the substrate W, and a three-dimensionally movable stage may be used as the stage 300. As the stage 300 moves, the substrate W may be moved together with the stage 300. For example, operations such as z-axis focusing or x-y plane scanning may be performed on the substrate W by moving the stage 300.

The substrate W may be a device such as a mask or a wafer having a plurality of repeating patterns in an array region. The substrate W may be a semiconductor device including measurement-target patterns in a cell area.

The detector 400 may detect an image, which is formed on a pupil plane PP1 by light L reflected from the substrate W. That is, the detector 400 may detect a pupil image. In FIG. 1, the pupil plane PP1 is illustrated by a dash-dotted line with respect to reflected light L from the substrate W. The relay lens 230 and the polarization state analyzer 240 may be arranged between the detector 400 and the pupil plane PP1. The pupil image detected on the pupil plane PP1 may be stored through the detection unit 400. The detector 400 may be a charge-coupled device (CCD) or a photo-multiplier tube (PMT).

In some embodiments of the present inventive concept, the overlay measurement system 1000 may non-destructively measure the overlay of patterns formed in a cell area of the substrate W. The overlay measurement system 1000 may perform overlay measurement and compensation at a relatively high measurement speed.

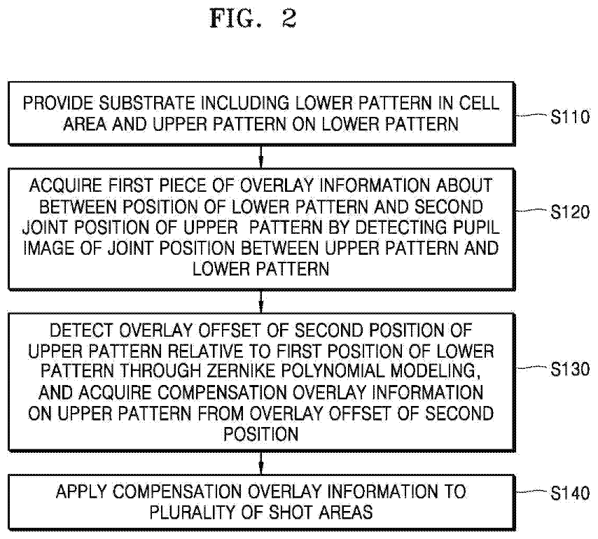

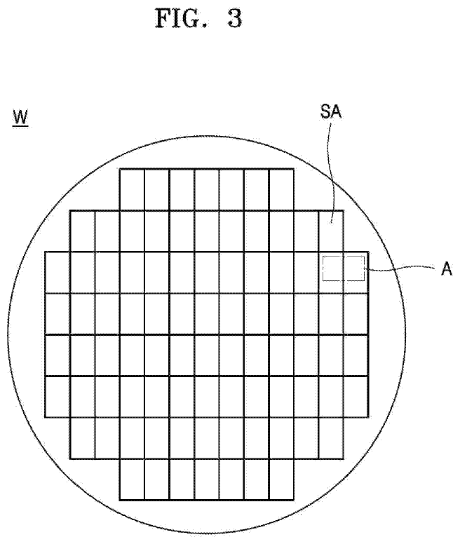

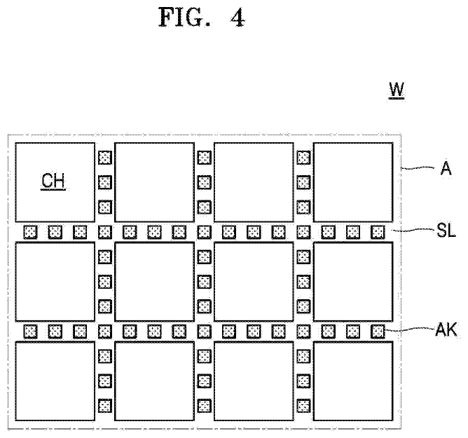

FIG. 2 is a flowchart illustrating an overlay measurement method according to an embodiment of the present inventive concept. FIG. 3 is a schematic diagram illustrating a substrate W used in an overlay offset measurement method according to an embodiment of the present inventive concept, and FIG. 4 is an enlarged view illustrating a portion A of FIG. 3.

Referring to FIGS. 2 to 4, a substrate W having a lower pattern in a cell area and an upper pattern on the lower pattern may be provided (operation S110).

The substrate W may include semiconductor devices such as DRAM devices or VNAND devices. Alignment keys AK or a multi-pattern layer may be formed on the substrate W to measure the alignment of the substrate W. For example, the alignment keys AK may include marks for adjusting the overlay or alignment of the substrate W between a first process and a second process following the first process during semiconductor device manufacturing processes. For example, the alignment keys AK may be used to measure the position of the substrate W in at least two periods among a period before a first exposure process for forming a first material pattern on the substrate W, a period after the first exposure process, a period after an etching process for forming the first material pattern, a period before a second exposure process for forming a second material pattern on the first material pattern, a period after the second exposure process, and a period after an etching process for forming the second material pattern.

As shown in FIGS. 2 and 3, the substrate W may include a plurality of shot areas SA, and each of the shot areas SA may be an area exposed through one exposing action. For example, when the substrate W includes 100 shot areas SA, 100 exposing actions may be performed on the substrate W.

Each of the shot areas SA may include a plurality of chip areas CH, and scribe lanes SL may be provided between the chip areas CH. A plurality of alignment keys AK may be arranged in each of the scribe lanes SL. For example, the alignment keys AK may be arranged in the scribe lanes SL at a predetermined distance from each other.

Each of the chip areas CH may include a cell area. The term “cell area” may refer to an area in which electronic elements or patterns are actually formed. For example, the term “cell area” may refer to an area that is provided spaced apart from scribe lanes SL and includes no alignment key AK. A pattern such as a channel hole or a contact hole, of which the overlay is to be measured, may be provided in a cell area.

In some embodiments of the present inventive concept, the substrate W may include a lower pattern formed in the cell area. For example, the lower pattern may include a lower channel hole formed through a lower stack that is disposed on the substrate. For example, the lower channel hole may have a circular cross-sectional shape in a horizontal direction. In some embodiments of the present inventive concept, an upper stack may be formed on the lower stack, and an upper pattern may include an upper channel hole formed through the upper stack. For example, the upper channel hole may have a circular cross-sectional shape in the horizontal direction and may communicate with the lower channel hole. For example, the upper channel hole may be connected to the lower channel hole.

In some embodiments, each of the lower channel hole and the upper channel hole may have a vertical height of about 1 micrometer to about 10 micrometers and a relatively large aspect ratio (for example, the ratio of a vertical height to a horizontal width).

In some embodiments of the present inventive concept, the substrate W may include a pattern that is likely to have a misalignment because of radial tilting. For example, a second position of an upper channel hole formed at the center of the substrate W that has a circular shape may be relatively less misaligned with a first position of a lower channel hole formed at the center of the substrate W, and a second position of an upper channel hole formed in an edge portion of the substrate W may have a relatively high misalignment with a first position of a lower channel hole formed in the edge portion of the substrate W. Therefore, overlay offset information detected at the center of the substrate W may be different from overlay offset information detected at the edge portion of the substrate W. Thus, overlay errors occurring at radial points of the substrate W due to radial tilting between lower channel holes and upper channel holes may be measured, analyzed, and corrected.

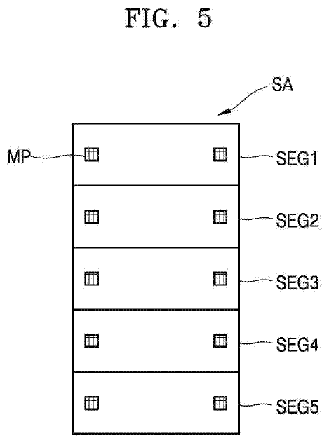

FIG. 5 is a view schematically illustrating a plurality of segments defined in a shot area SA.

Referring to FIGS. 2 and 5, a first piece of overlay information about a first position of a lower pattern and a second position of an upper pattern may be obtained by detecting a pupil image of a joint position between the upper pattern and the lower pattern (operation S120).

The substrate W is irradiated with light by using the overlay measurement system 1000 described with reference to FIG. 1, and the overlay measurement system 1000 may obtain the pupil image from light focused on the joint position between the upper pattern and the lower pattern. For example, when an upper channel hole has a vertical height of about 5 micrometers, the joint position between a lower channel hole and the upper channel hole may refer to a region having a depth of about 5 micrometers from an upper surface of an upper stack, and the overlay measurement system 1000 may emit focused light to a depth of about 5 micrometers from the upper surface of the upper stack and may store a pupil image obtained from light reflected therefrom.

As shown in FIG. 5, the first piece of overlay information may include segment overlay information about a plurality of segments corresponding to a plurality of shot areas SA that are provided on the substrate W. For example, segment overlay information may be obtained for upper and lower patterns arranged in each of a plurality of shot areas SA provided on the substrate W.

In some embodiments of the present inventive concept, each shot area SA may be divided into a plurality of segments SEG1 to SEG5. Each of the segments SEG1 to SEG5 may include measurement points MP at both ends thereof. For example, a pupil image of a vertical joint position between an upper pattern and a lower pattern may be obtained at a measurement point MP that is selected in a plan view from the measurement points MP of each of the segments SEG1 to SEG5. For example, although FIG. 5 illustrates an example in which each shot area SA includes first to fifth segments SEG1 to SEG5, the number of segments included in each shot area SA may be appropriately determined according to the size of shot areas SA and the types of patterns to be measured. For example, the number of segments included in each shot area SA may be four or less, or six or more.

Thereafter, for example, the overlay offset of the second position of the upper pattern relative to the first position of the lower pattern may be detected by Zernike polynomial modeling, and compensation overlay information may be obtained for the upper pattern from the overlay offset of the second position (operation S130).

In some embodiments of the present inventive concept, the overlay offset of the second position of the upper pattern relative to the first position of the lower pattern may be detected by Zernike polynomial modeling. The overlay offset of the second position of the upper pattern relative to the first position of the lower pattern may include a radial tilting component. For example, the radial tilting component may indicate a misalignment tendency in which the upper pattern tends to shift to the second position from the first position of the lower pattern in a radial direction of the substrate W. For example, the radial tilting component of the second position of the upper pattern may indicate that the overlay offset of the second position of the upper pattern relative to the first position of the lower pattern has a tendency in a radial direction from the center of the substrate W to the edge of the substrate W according to a certain function.

In some embodiments of the present inventive concept, the radial tilting component may be detected by Zernike polynomial modeling, and a Zernike function used for the Zernike polynomial modeling may be expressed using even Zernike polynomials (Equation 1 below) and odd Zernike polynomials (Equation 2 below).

Even Zernike Polynomials:

Zₙ^{m}(ρ,φ)=Rₙ^{m}(ρ) cos(mφ) Equation 1

Odd Zernike Polynomials:

Zₙ^{-m}(ρ,φ)=Rₙ^{m}(ρ) sin(mφ) Equation 2

In Equations 1 and 2, n≥m≥0 (m=0 for even Zernike polynomials), φ refers to an azimuthal angle, ρ refers to a radial distance (0≤ρ≤1), Rₙ^{m} refers to radial polynomials and may be expressed as follows,

$${R}_{n}^{m} ( ρ ) = {\sum }_{k = 0}^{\frac{n - m}{2}} \frac{{( - 1 )}^{k} ( n - k ) !}{k ! ( \frac{n + m}{2} - k ) ! ( \frac{n - m}{2} - k ) !} {ρ}^{n - 2 k}$$

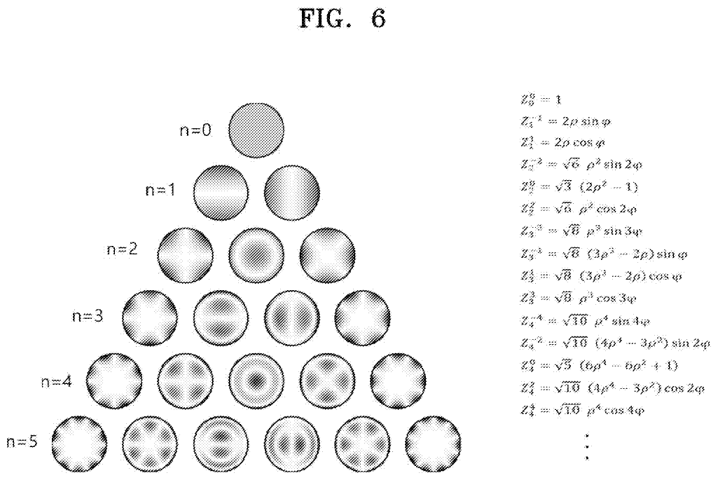

FIG. 6 is a diagram illustrating Zernike polynomials when the radial order n of the Zernike polynomials has a value of 0 to 5. Table 1 below shows the Zernike function when the radial order n has a value of 0 to 4.

TABLE 1

| n | m | zₙ^{m} |
|---|---|---|
| 0 | 0 | Z₀⁰ = 1 |
| 1 | −1 | Z₁⁻¹ = 2ρ sin φ |
| 1 | 1 | Z₁¹ = 2ρ cos φ |
| 2 | −2 | Z₂⁻² = \sqrt{6} ρ² sin 2φ |
| 2 | 0 | Z₂⁰ = \sqrt{3} (2ρ² − 1) |
| 2 | 2 | Z₂² = \sqrt{6} ρ² cos 2φ |
| 3 | −3 | Z₃⁻³ = \sqrt{8} ρ³ sin 3φ |
| 3 | −1 | Z₃⁻¹ = \sqrt{8} (3ρ³ − 2ρ) sin φ |
| 3 | 1 | Z₃¹ = \sqrt{8} (3ρ³ − 2ρ) cos φ |
| 3 | 3 | Z₃³ = \sqrt{8} ρ³ cos 3φ |
| 4 | −4 | Z₄⁻⁴ = \sqrt{10} ρ⁴ sin 4φ |
| 4 | −2 | Z₄⁻² = \sqrt{10} (4ρ⁴ − 3ρ²) sin 2φ |
| 4 | 0 | Z₄⁰ = \sqrt{5} (6ρ⁴ − 6ρ² + 1) |
| 4 | 2 | Z₄² = \sqrt{10} (4ρ⁴ − 3ρ²) cos 2φ |
| 4 | 4 | Z₄⁴ = \sqrt{10} ρ⁴ cos 4φ |

As shown in FIG. 6, the overlay offset of the second position of the upper pattern relative to the first position of the lower pattern may have a tendency according to at least one of Zernike polynomials having n within the range of 0 to 5 (n=0 to n=5).

In some embodiments of the present inventive concept, the overlay offset of the second position of the upper pattern relative to the first position of the lower pattern may be modeled by applying weights respectively to Zernike polynomials with n=0 to n=5. For example, regression analysis may be performed using a set of a first polynomial (n=0), a second polynomial (n=1, m=−1), a third polynomial (n=1, m=1), . . . , and a kth polynomial (n=u, m=v).

In some embodiments of the present inventive concept, the overlay offset of the second position of the upper pattern relative to the first position of the lower pattern may be modeled by applying weights respectively to Zernike polynomials with n=0 to n=6, or by applying weights respectively to Zernike polynomial functions with n=0 to n=4.

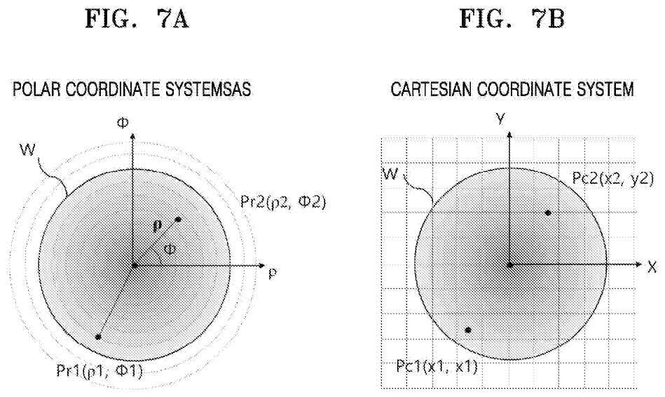

FIGS. 7A and 7B are schematic diagrams illustrating overlay offset mapping values as examples. FIG. 7A shows an overlay offset tendency mapped using a polar coordinate system or a radial coordinate system by an overlay offset measurement method according to an embodiment of the present inventive concept, and FIG. 7B shows an overlay offset tendency mapped using a Cartesian coordinate system by an overlay offset measurement method according to a comparative example. In FIGS. 7A and 7B, segment overlay offsets measured and analyzed for a plurality of shot areas of the substrate W are displayed in gray levels.

Referring to FIG. 7A, overlay offset mapping values of the substrate W may be closely matched to Zernike polynomials with n=2 and m=0. For example, overlay offset values may gradually decrease from the center of the substrate W to the edge of the substrate W. In addition, the overlay offset value at a first measurement point Pr1 (ρ1, Φ1) on the substrate W is relatively large (expressed in light gray), and the overlay offset value at a second measurement point Pr2 (ρ2, Φ2) is relatively small (expressed in dark gray).

When the overlay offset mapping values have a tilting component in a radial direction, points located at the same radial distance from the center of the substrate W (for example, points on a concentric circle) tend to have similar overlay offset values, and in this case, the Zernike polynomials expressed using the polar coordinate system shown in FIG. 7A may closely match overlay offset mapping of the substrate W. Therefore, when the overlay offset mapping values have a tilting component in a radial direction, overlay offsets may be effectively compensated for by using the Zernike polynomials.

In addition, referring to FIG. 7B, the overlay offset mapping values of the substrate W has a concentric circle profile that gradually decreases from the center of the substrate W to the edge of the substrate W. In addition, modeling for the overlay offset values at a first measurement point Pc1 (x1, y1) and a second measurement point Pr2 (x2, y2) in the Cartesian coordinate system might not be sufficient to completely compensate for a certain radial component.

Referring back to FIG. 2, compensation overlay information may be applied to a plurality of shot areas (operation S140).

In some embodiments of the present inventive concept, photolithography process parameters for forming a lower pattern on a subsequent substrate W may be adjusted or changed by using compensation overlay information that is detected by Zernike polynomial modeling. For example, process variables for each of a plurality of shot areas SA provided on a substrate W may be adjusted or compensated by using segment overlay offset information that is derived for each of the shot areas SA.

In some embodiments of the present inventive concept, compensation overlay information may be obtained by a regression analysis method or a machine learning method based on data obtained by performing overlay offset compensation procedures for a plurality of substrates W. For example, owing to the use of machining learning, compensation overlay offsets may be precisely derived in the compensation overlay information obtaining operation S130.

According to the overlay measurement method of the embodiments described with reference to FIGS. 2 to 7, a substrate W having a pattern that is likely to be misaligned due to tilting in a radial direction (for example, a substrate W having a joint structure for a lower channel hole and an upper channel hole that have a large aspect ratio) may be effectively compensated for overlay offsets. In addition, because overlay offsets are compensated for by using segment overlay offset information about each of a plurality of shot areas, effective compensation may be possible for vulnerable areas of a substrate such as an edge region of a substrate.

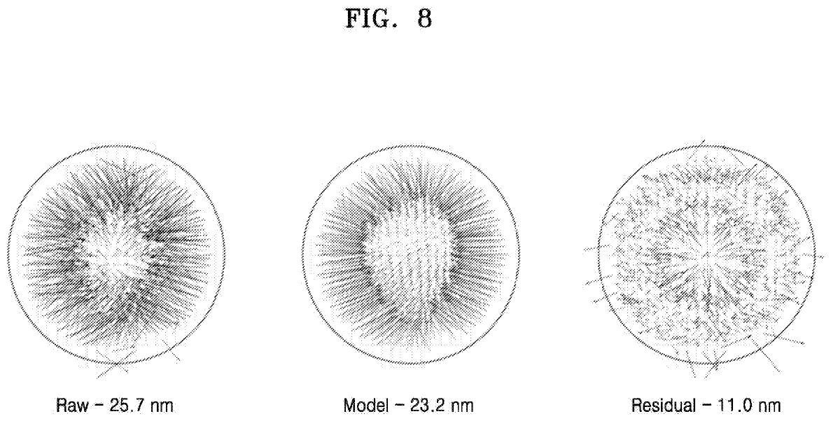

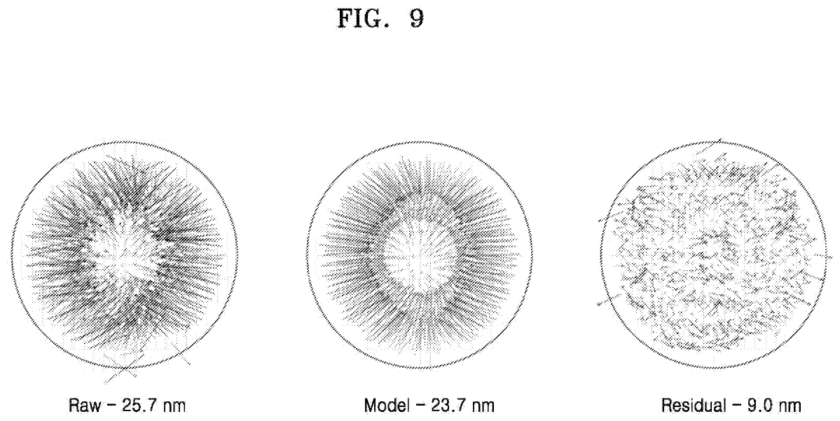

FIG. 8 is an overlay vector diagram obtained by an overlay measurement method using a Cartesian coordinate system according to a comparative example, and FIG. 9 is an overlay vector diagram obtained by an overlay measurement method according to some embodiments of the present inventive concept.

Referring to FIG. 8, the average of overlay offsets was about 25.7 nm before correction, and the average of overlay offsets was about 23.2 nm in modeling with a Cartesian coordinate system. After a compensation process was performed using results of the modeling, a residual overlay offset was about 11.0 nm. For example, an overlay offset may be reduced from about 25.7 nm to about 11.0 nm by deriving compensation overlay offset information through modeling using a Cartesian coordinate system, and by performing a compensation process based on the modeling.

Referring to FIG. 9, the average of overlay offsets was about 25.7 nm before correction, and the average of overlay offsets was about 23.2 nm in Zernike polynomial modeling with a polar coordinate system or a radial coordinate system. After a compensation process was performed using results of high-order modeling such as sixth or higher order modeling (i.e., using Zernike polynomials with n=0 to n=6, or more), a residual overlay offset was about 9.0 nm. That is, an overlay offset may be reduced from about 25.7 nm to about 9.0 nm by deriving compensation overlay offset information through Zernike polynomial modeling using a polar coordinate system, and by performing a compensation process based on the Zernike polynomial modeling. That is, overlay offsets were reduced by about 65%, and this shows that effective overlay offset compensation is possible by Zernike polynomial modeling.

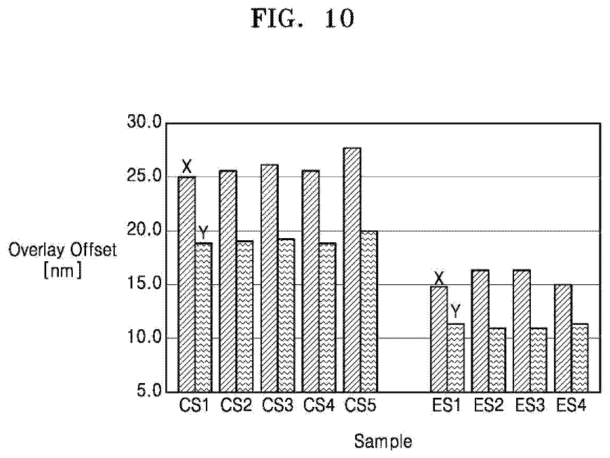

FIG. 10 is a graph illustrating overlay offsets (in nm) of measurement samples CS1 to CS5 according to a comparative example, and overlay offsets (in nm) of measurement samples ES1 to ES4 according to an embodiment of the present inventive concept.

FIG. 10 shows the overlay offsets of the measurement samples CS1 to CS5, of the comparative example, which were not compensated through Zernike polynomial modeling, and the overlay offsets of the measurement samples ES1 to ES4 which were compensated using results of high-order modeling (sixth or higher order modeling). This shows that the overlay offsets of patterns formed in cell areas may be effectively compensated for by using Zernike polynomial modeling.

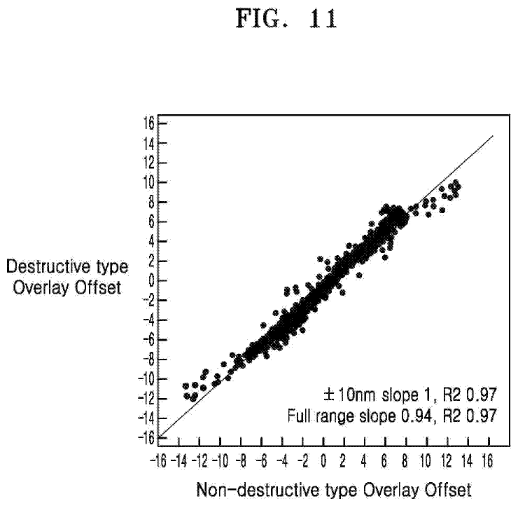

FIG. 11 is a graph illustrating a correlation between overlay offset values measured by a non-destructive overlay measurement method according to an embodiment of the present inventive concept and overlay offset values measured by a destructive measurement method.

Referring to FIG. 11, the overlay offset values measured by the non-destructive overlay measurement method of the embodiment have a high correlation with the overlay offset values measured by the destructive measurement method such as a method of cutting through an upper channel hole in a cell area. That is, reliable overlay measurement and compensation may be implemented by the non-destructive overlay measurement method of the present embodiment.

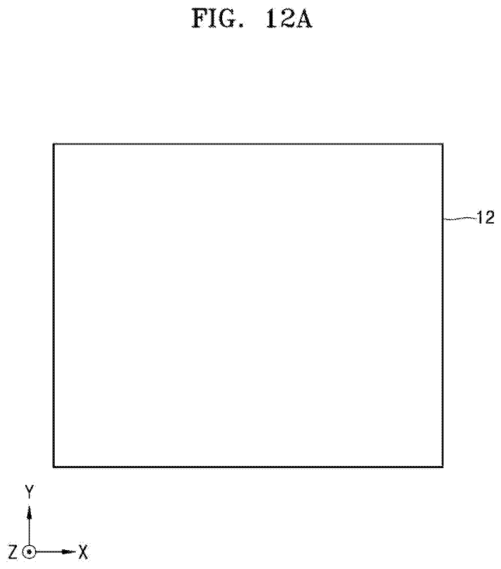

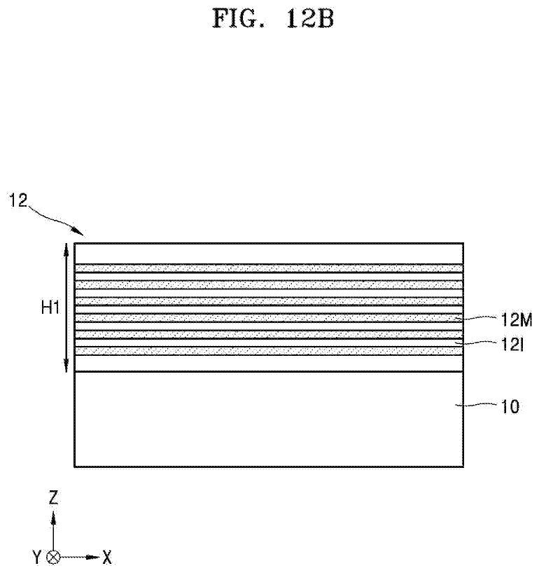

FIGS. 12A to 16B are schematic diagrams illustrating a method of manufacturing a semiconductor device according to an embodiment of the present inventive concept. FIG. 12A to 16B show a method of manufacturing a semiconductor device by the overlay measurement method described with reference to FIG. 2.

Referring to FIGS. 12A and 12B, a lower stack 12 may be formed on a substrate 10. The lower stack 12 may include a plurality of mold layers 12M and a plurality of insulating layers 12I that are alternately disposed in a vertical direction Z. For example, the vertical height H1 of the lower stack 12 may be about 1 micrometer to about 10 micrometers.

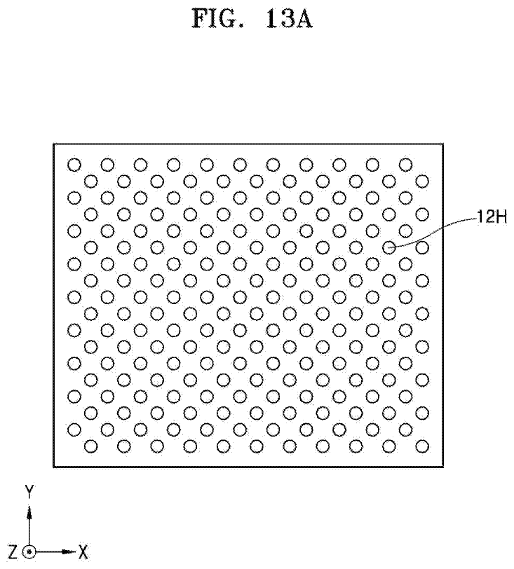

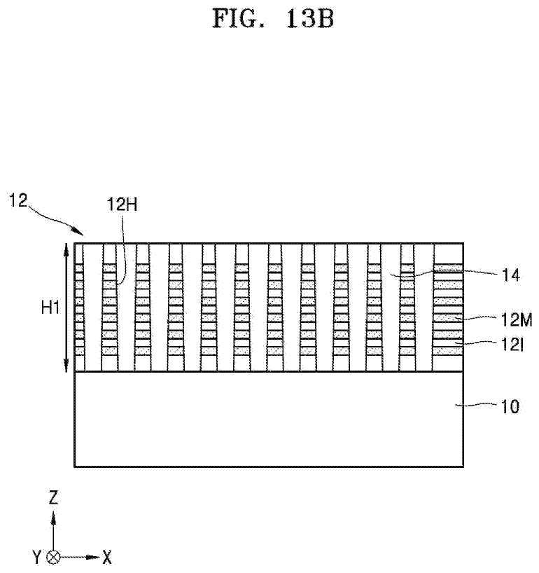

Referring to FIGS. 13A and 13B, a photolithography patterning process may be performed on the lower stack 12 to form a mask pattern, and portions of the lower stack 12 may be removed by using the mask pattern as an etch mask to form a plurality of lower channel holes 12H.

The lower channel holes 12H may be arranged in a zigzag shape in a first horizontal direction X and a second horizontal direction Y. For example, the lower channel holes 12H may be alternately arranged.

Thereafter, a protective layer 14 may be formed to fill the insides of the lower channel holes 12H.

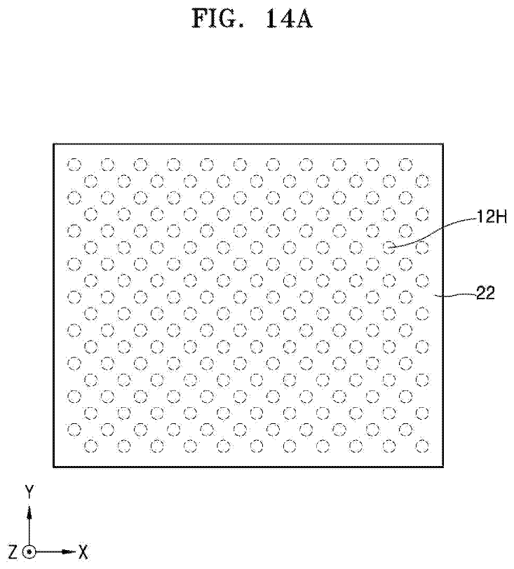

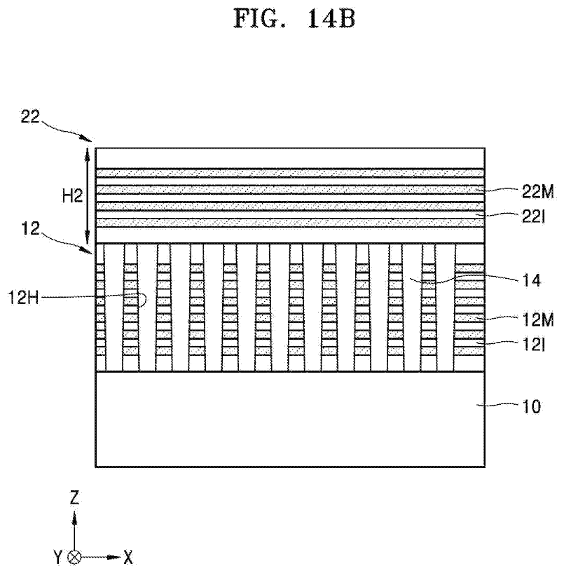

Referring to FIGS. 14A and 14B, an upper stack 22 may be formed on the lower stack 12. The upper stack 22 may include a plurality of mold layers 22M and a plurality of insulating layers 22I that are alternately disposed in the vertical direction Z. For example, the vertical height H2 of the upper stack 22 may be about 1 micrometer to about 10 micrometers.

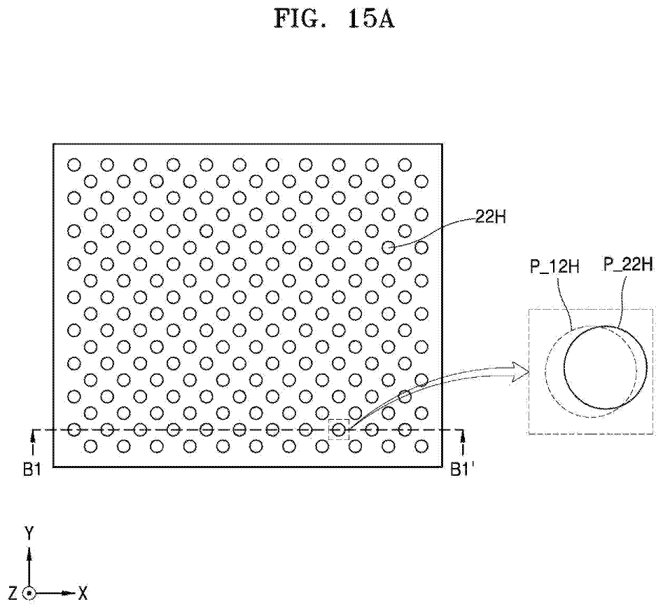

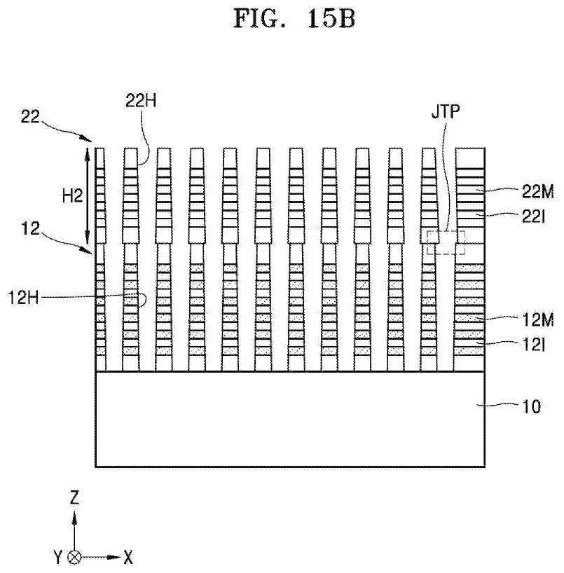

Referring to FIGS. 15A and 15B, a photolithography patterning process may be performed on the upper stack 22 to form a mask pattern, and a plurality of upper channel holes 22H may be formed by removing portions of the upper stack 22 using the mask pattern as an etch mask.

The upper channel holes 22H may be arranged in a zigzag shape in the first horizontal direction X and the second horizontal direction Y. For example, the upper channel holes 22H may be alternately arranged along the first horizontal direction X and the second horizontal direction Y. The upper channel holes 22H may vertically overlap the lower channel holes 12H, respectively.

In some embodiments of the present inventive concept, the process of forming the upper channel holes 22H may include an ion beam etching process. Because the upper channel holes 22H have a relatively large aspect ratio, ion beams may radially tilt during the process of forming the upper channel holes 22H. Radial tilting of ion beams may occur more at bottom portions of the upper channel holes 22H than at upper portions of the upper channel holes 22H, and thus, the positions P_22H of the bottom portions of the upper channel holes 22H may be misaligned with the positions P_12H of upper portions of the lower channel holes 12H. Therefore, overlay offsets may occur at joint regions JTP between the bottom portions of the upper channel holes 22H and the upper portions of the lower channel holes 12H.

According to some embodiments of the present inventive concept, overlay offsets caused by radial tilting may be compensated for by a cell-area overlay measurement method and the Zernike polynomial modeling method described with reference to FIG. 2, and thus, overlay offsets between the upper channel holes 22H and the lower channel holes 12H may be effectively reduced.

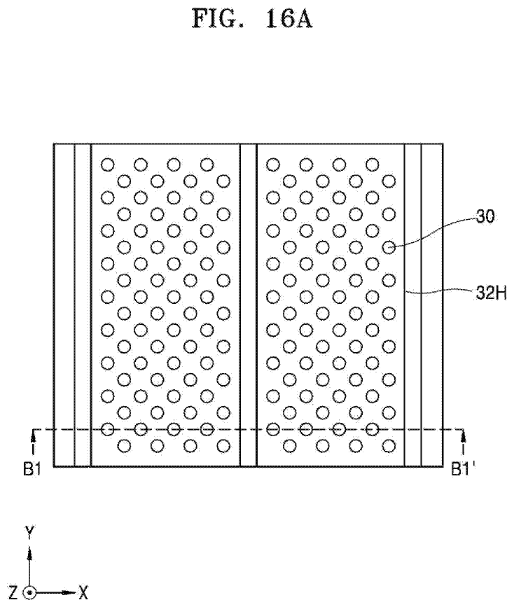

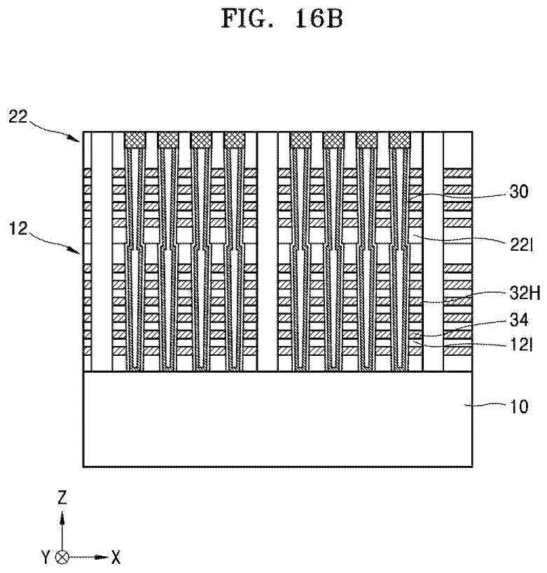

Referring to FIGS. 16A and 16B, channel structures 30 may be formed in the upper channel holes 22H and the lower channel holes 12H. Thereafter, portions of the upper stack 22 and the lower stack 12 may be removed to form word line cut regions 32H, and the mold layers 12M and 22M exposed through the word line cut regions 32H may be removed. Then, gate electrodes 34 may be formed in portions from which the mold layers 12M and 22M are removed.

A semiconductor device may be manufactured through the processes described above.

In the embodiments of the present inventive concept described above, the overlay offset measurement method and the compensation method are performed, for example, on the joint regions JTP between the lower channel holes 12H and the upper channel holes 22H. In some embodiments of the present inventive concept, however, the overlay offset measurement method and the compensation method may be performed in a process of forming high-aspect-ratio openings for forming cell contacts connected to the gate electrodes 34, peripheral circuit contacts, or through-vias.

Furthermore, in the embodiments described above, the overlay offset measurement method and the compensation method are performed, for example, on the semiconductor device having the channel structures 30 extending in a vertical direction. In some embodiments of the present inventive concept, however, the overlay offset measurement method and the compensation method may be performed in a process of forming high-aspect-ratio openings in a DRAM device, a phase-change random access memory (PRAM) device, a magnetoresistive random access memory (MRAM) device, or the like having buried channel transistors.

While the present inventive concept has been described with reference to embodiments thereof, it will be understood by those of ordinary skill in the art that various changes in form and details may be made thereto without departing from the spirit and scope of the present inventive concept.

What is claimed is:

1. A method of measuring an overlay offset, the method comprising:
providing a substrate comprising a lower pattern and an upper pattern, wherein the lower pattern is disposed in a cell area, and the upper pattern is disposed on the lower pattern;
acquiring a first piece of overlay information about a first position of the lower pattern and a second position of the upper pattern by detecting a pupil image of a joint position that is between the upper pattern and the lower pattern;
detecting an overlay offset of the second position of the upper pattern relative to the first position of the lower pattern through Zernike polynomial modeling; and
acquiring compensation overlay information on the upper pattern from the overlay offset of the second position,
wherein the overlay offset comprises a radial tilting component.

2. The method of claim 1, wherein a Zernike function used in a Zernike polynomial modeling is expressed as:
even Zernike polynomials, Zₙ^{m}(ρ,φ)=Rₙ^{m}(ρ) cos(mφ), and
odd Zernike Polynomials, Zₙ^{-m}(ρ,φ)=Rₙ^{m}(ρ) sin(mφ),
where n≥m≥0 (m=0 for even Zernike polynomials), φ is an azimuthal angle, ρ is a radial distance, 0≤p≤1, Rₙ^{m} are radial polynomials defined as below,
$${R}_{n}^{m} ( ρ ) = {\sum }_{k = 0}^{\frac{n - m}{2}} \frac{{( - 1 )}^{k} ( n - k ) !}{k ! ( \frac{n + m}{2} - k ) ! ( \frac{n - m}{2} - k ) !} {ρ}^{n - 2 k} .$$

3. The method of claim 1, wherein the detecting of the overlay offset comprises deriving a correlation that is between the overlay offset and the compensation overlay information by using at least one of Zernike polynomials of the Zernike function with n that is within a range of 0 to 6.

4. The method of claim 3, wherein the deriving of the correlation between the overlay offset and the compensation overlay information comprises deriving a residual overlay vector value between the overlay offset and a value obtained through the Zernike polynomial modeling.

5. The method of claim 4, wherein the residual overlay vector value comprises overlay offset information corrected as a result of a process performed to compensate for overlay offsets occurring at a plurality of positions of the substrate by using compensation overlay information.

6. The method of claim 1, wherein the acquiring of the first piece of overlay information comprises acquiring a plurality of pieces of segment overlay information corresponding to each of a plurality of shot areas of the substrate, and
the acquiring of the compensation overlay information comprises acquiring a plurality of pieces of compensation segment overlay information from the plurality of pieces of segment overlay information to compensate for the radial tilting component.

7. The method of claim 6, further comprising performing a compensation process for an edge region of the substrate by using compensation segment overlay information that is different from compensation segment information used for a center region of the substrate.

8. The method of claim 6, wherein the joint position has a height of about 1 micrometer to about 10 micrometers from an upper surface of the upper pattern.

9. The method of claim 6, wherein the acquiring of the first piece of overlay information comprises detecting, as the pupil image, light reflected to a pupil plane from the joint position between the lower pattern and the upper pattern in the cell area of the substrate for a measurement point that is selected from each of the plurality of shot areas.

10. The method of claim 1, wherein the acquiring of the compensation overlay information comprises acquiring the compensation overlay information by a regression method or a machine learning method.

11. The method of claim 1, wherein the lower pattern comprises a lower channel hole, and
the upper pattern comprises an upper channel hole.

12. The method of claim 11, wherein the providing of the substrate comprises:
forming a lower stack on the substrate;
forming the lower channel hole, which extend in a vertical direction substantially perpendicular to an upper surface of the substrate, by removing a portion of the lower stack;
forming an upper stack on the lower stack, wherein the upper stack covers the lower channel hole; and
forming the upper channel hole, which extends in the vertical direction and overlaps with the lower channel hole by removing a portion of the upper stack.

13. The method of claim 12, wherein the forming of the upper channel hole comprises performing an ion beam etching process, and
the radial tilting component is caused by radial tilting of ions used in the ion beam etching process.

14. A method of measuring an overlay offset, the method comprising:
providing a substrate comprising a lower channel hole and an upper channel hole, wherein the lower channel hole is disposed in a cell area, and the upper channel hole is disposed on the lower channel hole;
acquiring a first piece of overlay information about a first position of the lower channel hole and a second position of the upper channel hole by detecting a pupil image of a joint position that is between the lower channel hole and the upper channel hole;
detecting an overlay offset of the second position of the upper channel hole relative to the first position of the lower channel hole through Zernike polynomial modeling; and
acquiring compensation overlay information on the upper channel hole from the overlay offset of the second position,
wherein the overlay offset is caused by a radial tilting error of the upper channel hole.

15. The method of claim 14, wherein a Zernike function used in the Zernike polynomial modeling is expressed as:
even Zernike polynomials, Zₙ^{m}(ρ,φ)=Rₙ^{m}(ρ) cos(mφ), and
odd Zernike Polynomials, Zₙ^{-m}(ρ,φ)=Rₙ^{m}(ρ) sin(mφ),
where n≥m≥0 (m=0 for even Zernike polynomials), φ is an azimuthal angle, ρ is a radial distance, 0≤ρ≤1, Rₙ^{m} are radial polynomials defined as below,
$${R}_{n}^{m} ( ρ ) = {\sum }_{k = 0}^{\frac{n - m}{2}} \frac{{( - 1 )}^{k} ( n - k ) !}{k ! ( \frac{n + m}{2} - k ) ! ( \frac{n - m}{2} - k ) !} {ρ}^{n - 2 k} .$$

16. The method of claim 1, wherein the detecting of the overlay offset comprises deriving a correlation that is between the overlay offset and the compensation overlay information by using at least one of Zernike polynomials of a Zernike function with n that is within a range of 0 to 6.

17. The method of claim 14, wherein the acquiring of the first piece of overlay information comprises acquiring a plurality of pieces of segment overlay information corresponding to each of a plurality of shot areas of the substrate, and
the acquiring of the compensation overlay information comprises acquiring a plurality of pieces of compensation segment overlay information from the plurality of pieces of segment overlay information to compensate for a radial tilting component.

18. The method of claim 17, further comprising performing a compensation process for an edge region of the substrate by using compensation segment overlay information that is different from compensation segment information used for a center region of the substrate.

19. A method of manufacturing a semiconductor device, the method comprising:
forming a lower stack in a cell area of a substrate, wherein the lower stack comprises a lower channel hole;
forming an upper stack on the lower stack, wherein the upper stack comprises an upper channel hole;
acquiring a first piece of overlay information about a first position of the lower channel hole and a second position of the upper channel hole by detecting a pupil image of a joint position that is between the upper channel hole and the lower channel hole;
detecting an overlay offset of the second position of the upper channel hole relative to the first position of the lower channel hole through Zernike polynomial modeling; and
acquiring compensation overlay information on the upper channel hole from the overlay offset of the second position,
wherein the overlay offset comprises a radial tilting component.

20. The method of claim 19, wherein the forming of the upper channel hole comprises performing an ion beam etching process, and
the radial tilting component is caused by radial tilting of ions used in the ion beam etching process.
